(19) United States
(12) Patent Application Publication
(10) Pub. No.: US 2010/0214734 A1
(43) Pub. Date: Aug. 26, 2010

(54) HEAT DISSIPATING MECHANISM HAVING ENHANCED HEAT DISSIPATING EFFICIENCY WITH JETS AND RELATED ELECTRONIC DEVICE

(76) Inventors: Shih-Huai Cho, Taipei Hsien (TW); Ming-Chang Wu, Taipei Hsien (TW); Jeng-Ming Lai, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/643,981

(22) Filed: Dec. 21, 2009

(30) Foreign Application Priority Data
Feb. 20, 2009 (TW) 098202515

(51) Int. Cl. G06F 1/20; H05K 7/20

(52) U.S. Cl. 361/679.46; 165/121; 361/694; 361/695

(57) ABSTRACT

A heat dissipating mechanism includes a housing. A hollow space is formed inside the housing. The heat dissipating mechanism further includes an airflow guiding structure installed inside the hollow space for separating the hollow space into a first channel and a second channel. An inlet and an outlet are formed on the airflow guiding structure. Airflow enters the first channel via the inlet and jets out of the outlet for mixing with thermal current generated by a heat source in the second channel.

### BACKGROUND OF THE INVENTION

1. Field of the Invention

The present invention relates to a heat dissipating mechanism and a related electronic device, and more particularly, to a heat dissipating mechanism having enhanced heat dissipating efficiency with jets and a related electronic device.

2. Description of the Prior Art

Consumer electronic products have more and more functions with progress of technology. Hence the demand for performance increases accordingly. The high performance brings high energy consumption resulting in resonance, noise, thermal problems, and so on. For example, the reliability and stability of electronic products reduce if heat generated by internal electronic components can not be dissipated effectively. The conventional solution of thermal problem is utilizing a thermal system, such as a fan, a heat sink, a heat pipe, or a cooling chip for reducing temperature of the electronic components so that the electronic products can operate normally.

For instance, in order to dissipate heat generated by a memory module of a computer system in an air-cool manner effectively, bypass airflow is blocked directly for increasing efficient heat-dissipating airflow in heat area so as to promote heat dissipating efficiency of the memory module. Please refer to FIG. 1 and FIG. 2. FIG. 1 is a diagram of a heat dissipating mechanism of an electronic device 10 in the prior art. FIG. 2 is a lateral view of the heat dissipating mechanism of the electronic device 10 in the prior art. The electronic device 10 includes a housing 12 for covering internal elements, and a block 14 screwed on an inner side of the housing 12. The electronic device 10 further includes a heat source 16 installed inside the housing 12. The heat source 16 can be a memory module. Combination of the block 14 and the housing 12 can block the upper bypass airflow directly, so that airflow for cooling the heat source 16 can directly enter into the lower heat area, where the heat source 16 is disposed, so as to cool the heat source 16 effectively. However, this conventional structure increases system flow resistance extensively, and a pre-heated effect of the airflow causes large temperature difference between a front end and a rear end of the heat source 16, so that heat dissipating efficiency of the heat source 16 is decreased. Besides, a flow field of the conventional structure forms fully developed flow easily, and a boundary effect of the flow field reduces heat dissipating efficiency, so that the conventional heat dissipating mechanism can not achieve an optimum heat dissipating efficiency.

### SUMMARY OF THE INVENTION

The present invention provides a heat dissipating mechanism having enhanced heat dissipating efficiency with jets and a related electronic device for solving above drawbacks

According to the claimed invention, a heat dissipating mechanism includes a housing and an airflow guiding structure installed inside the hollow space of the housing for separating the hollow space into a first channel and a second channel. A hollow space is formed inside the housing. An inlet and an outlet are formed on the airflow guiding structure so that airflow enters the first channel via the inlet and jets out of the outlet for mixing with thermal current generated by a heat source in the second channel.

According to the claimed invention, the airflow guiding structure is a covering connected to an inner side of the housing.

According to the claimed invention, the airflow guiding structure is screwed on the inner side of the housing.

According to the claimed invention, an airflow guiding plate is disposed on a side of the outlet for guiding the airflow out of the outlet.

According to the claimed invention, an angle is formed between the airflow guiding plate and the housing so as to control an angle of the airflow jetting out of the outlet.

According to the claimed invention, an end of the airflow guiding structure opposite to the inlet is a closed end.

According to the claimed invention, the heat dissipating mechanism further includes a heat dissipating element for driving the airflow to flow to the first channel and the second channel.

According to the claimed invention, the heat dissipating element is a fan.

According to the claimed invention, an electronic device includes a housing, an airflow guiding structure installed inside the hollow space of the housing for separating the hollow space into a first channel and a second channel, a heat source installed inside the second channel, and a heat dissipating element for driving airflow to flow to the first channel and the second channel so that the airflow enters the first channel via the inlet and jets out of the outlet for mixing with thermal current generated by the heat source in the second channel. A hollow space is formed inside the housing. An inlet and an outlet are formed on the airflow guiding structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a heat dissipating mechanism of an electronic device in the prior art.

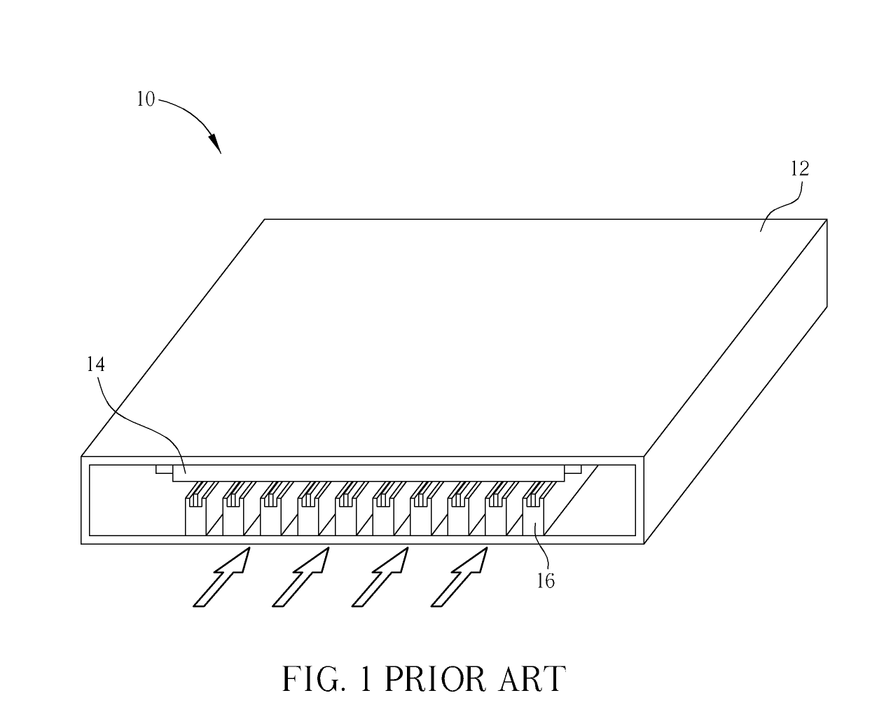

FIG. 2 is a lateral view of the heat dissipating mechanism of the electronic device in the prior art.

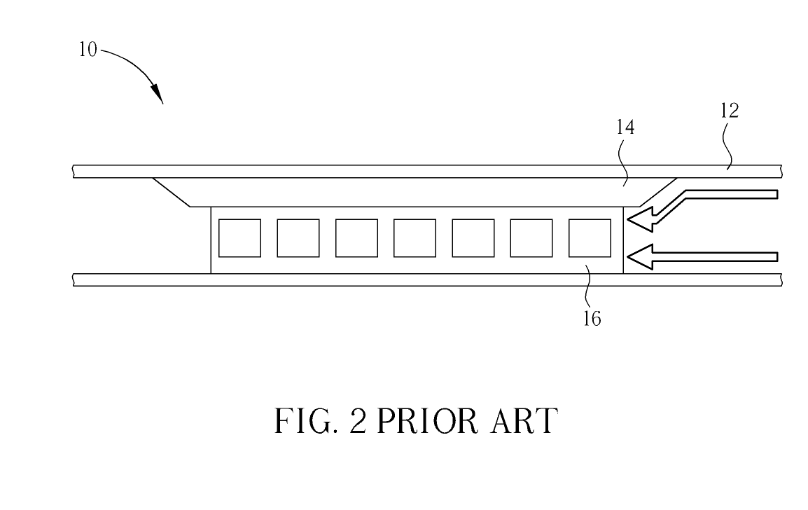

FIG. 3 is a diagram of a heat dissipating mechanism of an electronic device according to a preferred embodiment of the present invention.

FIG. 4 is a lateral view of the heat dissipating mechanism of the electronic device according to the preferred embodiment of the present invention.

FIG. 5 is a lateral view of a heat dissipating mechanism of an electronic device according to another preferred embodiment of the present invention.

### DETAILED DESCRIPTION

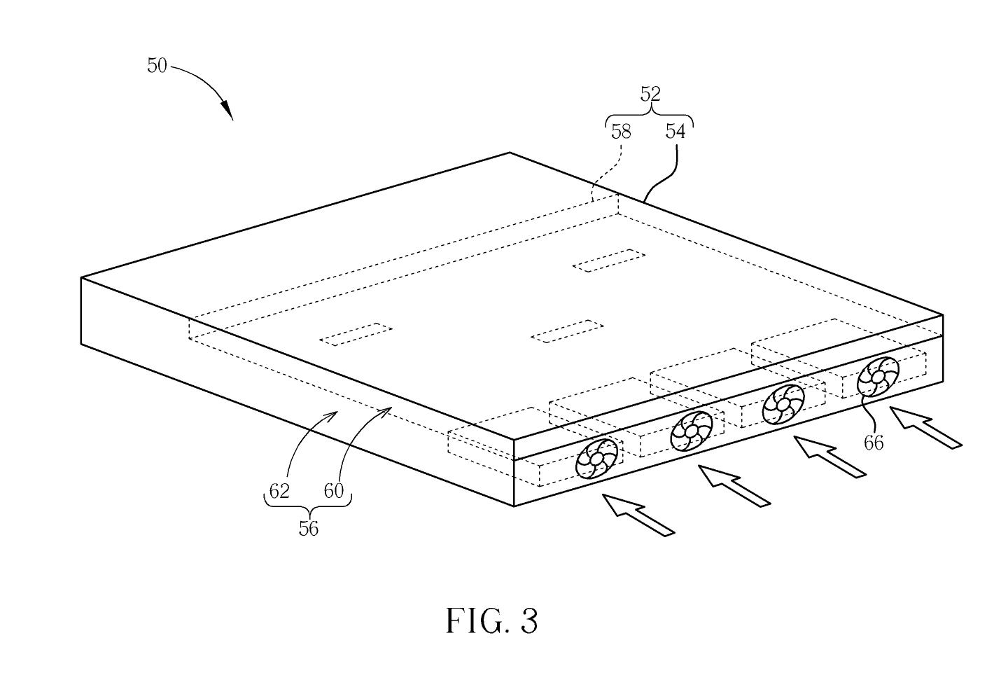

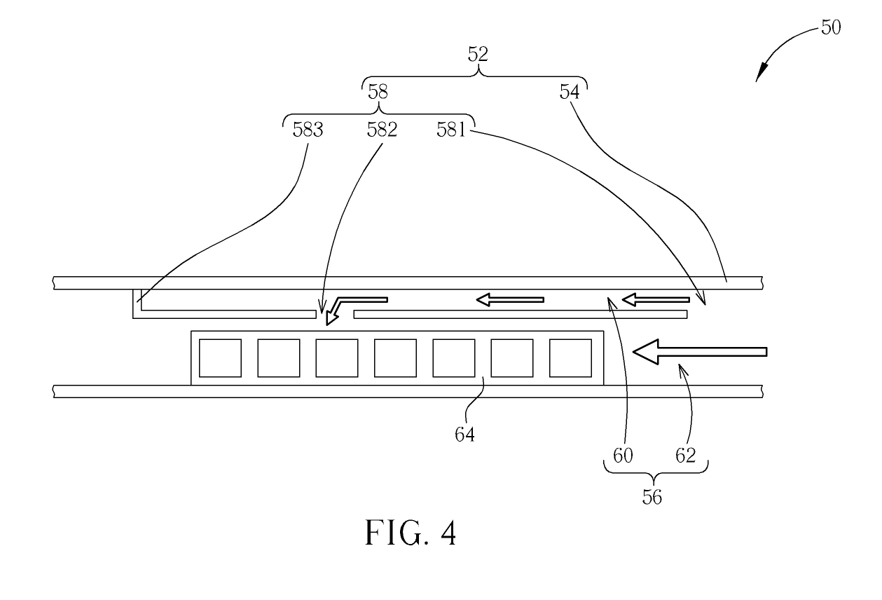

Please refer to FIG. 3 and FIG. 4. FIG. 3 is a diagram of a heat dissipating mechanism of an electronic device 50 according to a preferred embodiment of the present invention. FIG. 4 is a lateral view of the heat dissipating mechanism of the electronic device 50 according to the preferred embodiment of the present invention. The electronic device 50 includes a heat dissipating mechanism 52 including a housing 54. A hollow space 56 is formed inside the housing 54. The heat dissipating mechanism 52 further includes an airflow guiding structure 58 installed inside the hollow space 56 of the housing 54 for separating the hollow space 56 into a first channel 60 and a second channel 62. The electronic device 50 further includes a heat source 64 installed inside the second channel 62. In this embodiment, the heat source 64 can be a memory module, and the heat source 64 can be a storage device, such as a hard disc, an optical disk drive, and so on. The heat source 64 further can be a heating chip, such as a display chip, a south/north bridge chip, and so on. The airflow guiding structure 58 can be a covering connected to an inner side of the housing 54. For example, the covering can be screwed on the inner side of the housing 54. An inlet 581 and an outlet 582 are formed on the airflow guiding structure 58. The inlet 581 is disposed on an end of the airflow guiding structure 58, and the outlet 582 is disposed on a side of the airflow guiding structure 58 facing the heat source 64. An end of the airflow guiding structure 58 opposite to the inlet 581 is a closed end 583, which means airflow can not pass through the closed end 583 of the airflow guiding structure 58.

In addition, the electronic device 50 further includes at least one heat dissipating element 66 for driving the airflow to enter the first channel 60 and the second channel 62. The heat dissipating element 66 can be a fan for driving the airflow to enter the first channel 60 and the second channel 62 in an inhaling manner or in an exhaling manner, which means the heat dissipating element 66 can be disposed on front ends or rear ends of the first channel 60 and the second channel 62. As shown in FIG. 3, when the heat dissipating element 66 is disposed on the front ends of the first channel 60 and the second channel 62, the heat dissipating element 66 can drive the airflow to enter the first channel 60 and the second channel 62 in the exhaling manner. Besides, when the heat dissipating element 66 is disposed on the rear ends of the first channel 60 and the second channel 62, the heat dissipating element 66 can drive the airflow to enter the first channel 60 and the second channel 62 in the inhaling manner. The airflow entering the second channel 62 can dissipate heat generated by the heat source 64 in a convectional manner. Therefore, temperature of the airflow passing through the heat source 64 and reaching the rear end of the second channel 62 rises. On the other hand, because the airflow entering the first channel 60 via the inlet 581 does not mix with thermal current surrounding the heat source 64, temperature of the airflow in the first channel 60 is lower than the thermal current in the second channel 62. After cold current flows through the first channel 60 and arrives the outlet 582, the cold current in the second channel 62 jets into the first channel 60 via the outlet 582 to mix with the thermal current in the rear end of the first channel 60, which is pre-heated by the heat source 64. Therefore, a drawback of incapability of cooling the rear end of the heat source 64 due to the airflow pre-heated by the front end of the heat source 64 after flowing through the first channel 60 can be improved effectively. The cold current in the second channel 62 mixing with the thermal current in the first channel 60 at the rear end of the heat source 64 not only can decrease the temperature of the rear end of the heat source 64 directly, but also can effectively cool a heat point accurately by bypass airflow. Furthermore, the fully developed boundary of the flow field can be destroyed to increase intensity of turbulence for improving heat dissipating efficiency. Simultaneously, system flow resistance is not increased extensively, and the efficiency of heat dissipating is not affected by descending airflow. The number and disposition of the outlet 582 of the present invention are not limited to this embodiment. For example, the outlet 582 can be disposed corresponding to heat area being focused on heat dissipation, and it can be designed according to actual demand.

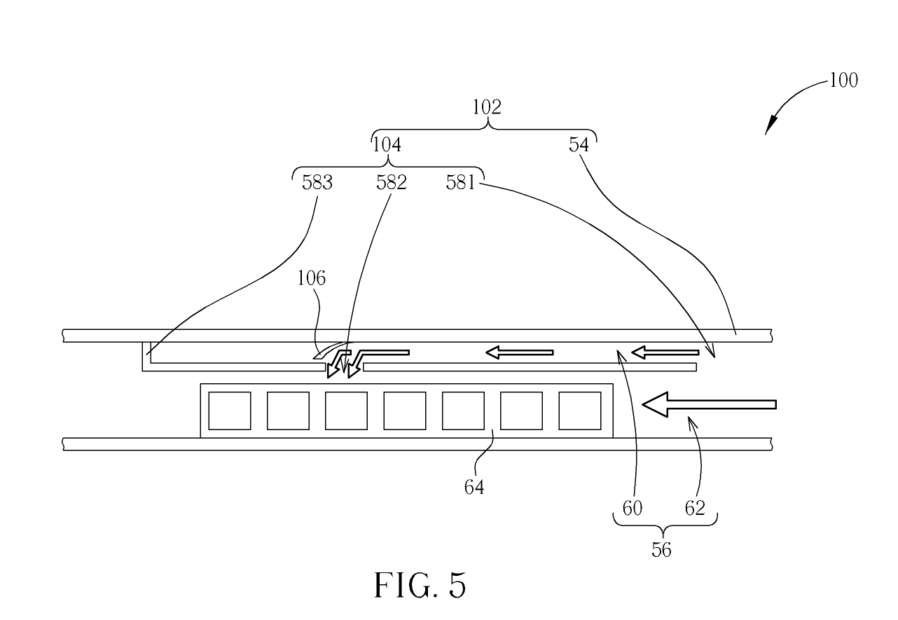

Please refer to FIG. 5. FIG. 5 is a lateral view of a heat dissipating mechanism of an electronic device 100 according to another preferred embodiment of the present invention. In this embodiment, elements having the same numerals as ones of the above-mentioned embodiment have the same structures and functions. The electronic device 100 includes a heat dissipating mechanism 102 including the housing 54. The hollow space 56 is formed inside the housing 54. The heat dissipating mechanism 102 further includes an airflow guiding structure 104 installed inside the hollow space 56 of the housing 54 for separating the hollow space 56 into the first channel 60 and the second channel 62. The electronic device 50 further includes the heat source 64 installed inside the second channel 62. The airflow guiding structure 104 can be a covering connected to the inner side of the housing 54. For example, the covering can be screwed on the inner side of the housing 54. The inlet 581 and the outlet 582 are formed on the airflow guiding structure 104. The inlet 581 is disposed on an end of the airflow guiding structure 104, and the outlet 582 is disposed on a side of the airflow guiding structure 104 facing the heat source 64. An end of the airflow guiding structure 104 opposite to the inlet 581 is the closed end 583, which means the airflow can not pass through the closed end 583 of the airflow guiding structure 104. Difference between this embodiment and the above-mentioned embodiment is that an airflow guiding plate 106 is disposed on a side of the outlet 582 for guiding the airflow to jet out of the outlet 582. The airflow guiding plate 106 can be connected to the inner side of the housing 54, and an angle is formed between the airflow guiding plate 106 and the housing 54 so as to control an angle of the airflow jetting out of the outlet 582. Similarly with the above-mentioned embodiment, the airflow guiding structure 104 also utilizes current separation to guide the bypass cold current to the heat point so as to decrease the temperature of the airflow at the rear end of the heat source 64. The angle of the cold current entering the second channel 62 can be controlled according to the designed angle of the airflow guiding plate 106. For example, the boundary layer developed at the front end of the first channel 60 can be destroyed by vertical jet or inclined jet, so that the intensity of turbulence at the rear end of the flow field can be increased to improve the heat dissipating efficiency. The number, angle, and disposition of the airflow guiding plate 106 are not limited to this embodiment and can be designed according to actual demand.

In conclusion, the present invention utilizes the bypass cold current to cool specific heat area, and can also increase the intensity of turbulence to solve reduction of heat transferring efficiency, which is caused by the fully developed current, so as to improve the heat dissipating efficiency. Comparing to an upper covering blocking the bypass airflow completely in the prior art, the heat dissipating mechanism with jets of the present invention not only can decrease flow resistance, but also can increase quantity of the airflow effectively by way of controlling positions where the cold current enters, which is unnecessary to promote function of the fan, so as to increase heat dissipating efficiency of the memory module. Temperature of the heat area at the rear end of the memory module can be decreased for improving stability and service life of the memory module. The present invention can also utilize the airflow generated by the fan effectively, so that there is no need to increase rotational speed of the fan so as to economize energy and reduce noise.

Comparing to the prior art, the heat dissipating mechanism of the present invention utilizes the jet to increase the heat dissipating efficiency, which not only can cool the specific heat area by the bypass cold current, but also can increase the intensity of turbulence to solve reduction of heat dissipating efficiency, which is caused by the fully developed current. In conclusion, the present invention truly provides an effective heat dissipating solution.

Those skilled in the art will readily observe that numerous modifications and alterations of the device and method may be made while retaining the teachings of the invention.

What is claimed is:

1. A heat dissipating mechanism comprising:
a housing, a hollow space being formed inside the housing; and
an airflow guiding structure installed inside the hollow space of the housing for separating the hollow space into a first channel and a second channel, an inlet and an outlet being formed on the airflow guiding structure so that airflow enters the first channel via the inlet and jets out of the outlet for mixing with thermal current generated by a heat source in the second channel.

2. The heat dissipating mechanism of claim 1, wherein the airflow guiding structure is a covering connected to an inner side of the housing.

3. The heat dissipating mechanism of claim 2, wherein the airflow guiding structure is screwed on the inner side of the housing.

4. The heat dissipating mechanism of claim 1, wherein an airflow guiding plate is disposed on a side of the outlet for guiding the airflow out of the outlet.

5. The heat dissipating mechanism of claim 4, wherein an angle is formed between the airflow guiding plate and the housing so as to control an angle of the airflow jetting out of the outlet.

6. The heat dissipating mechanism of claim 1, wherein an end of the airflow guiding structure opposite to the inlet is a closed end.

7. The heat dissipating mechanism of claim 1 further comprising:
a heat dissipating element for driving the airflow to flow to the first channel and the second channel.

8. The heat dissipating mechanism of claim 7, wherein the heat dissipating element is a fan.

9. An electronic device comprising:
a housing, a hollow space being formed inside the housing;
an airflow guiding structure installed inside the hollow space of the housing for separating the hollow space into a first channel and a second channel, an inlet and an outlet being formed on the airflow guiding structure;
a heat source installed inside the second channel; and
a heat dissipating element for driving airflow to flow to the first channel and the second channel so that the airflow enters the first channel via the inlet and jets out of the outlet for mixing with thermal current generated by the heat source in the second channel.

10. The electronic device of claim 9, wherein the airflow guiding structure is a covering connected to an inner side of the housing.

11. The electronic device of claim 10, wherein the airflow guiding structure is screwed on the inner side of the housing.

12. The electronic device of claim 9, wherein an airflow guiding plate is disposed on a side of the outlet for guiding the airflow out of the outlet.

13. The electronic device of claim 12, wherein an angle is formed between the airflow guiding plate and the housing so as to control an angle of the airflow jetting out of the outlet.

14. The electronic device of claim 9, wherein an end of the airflow guiding structure opposite to the inlet is a closed end.

15. The electronic device of claim 9, wherein the heat dissipating element is a fan.

16. The electronic device of claim 9, wherein the heat source is a memory module.
